(19) United States
(12) Patent Application Publication
(10) Pub. No.: US 2025/0098200 A1
(43) Pub. Date: Mar. 20, 2025

(54) GALLIUM NITRIDE ENHANCEMENT MODE DEVICE

(71) Applicant: Analog Devices, Inc., Wilmington, MA (US)

(72) Inventors: James G. Fiorenza, Carlisle, MA (US); Puneet Srivastava, Wilmington, MA (US); Daniel Piedra, Somerville, MA (US)

(21) Appl. No.: 18/940,279

(22) Filed: Nov. 7, 2024

Related U.S. Application Data
(62) Division of application No. 17/275,527, filed on Mar. 11, 2021.
(60) Provisional application No. 62/729,596, filed on Sep. 11, 2018.

(51) Int. Cl. H01L 29/778; H01L 21/265; H01L 21/266; H01L 27/088; H01L 29/06; H01L 29/20; H01L 29/205; H01L 29/417; H01L 29/423; H01L 29/66

(52) U.S. Cl. CPC H10D 30/475; H01L 21/26553; H10D 30/015; H10D 62/124; H10D 64/256; H10D 64/513; H10D 84/84; H01L 21/266; H10D 62/824; H10D 62/8503

(57) ABSTRACT

An enhancement mode compound semiconductor field-effect transistor (FET) includes a source, a drain, and a gate located therebetween. The transistor further includes a first gallium nitride-based hetero-interface located under the gate and a buried region, located under the first hetero-interface, the buried p-type region configured to determine an enhancement mode FET turn-on threshold voltage to permit current flow between the source and the drain.

### CLAIM OF PRIORITY

This application is a division of U.S. patent application Ser. No. 17/275,527, filed on Mar. 11, 2021, which is a U.S. National Stage Application which claims priority to PCT Application Serial No. PCT/US2019/050588, filed Sep. 11, 2019, and published as WO 2020/055984 A1 on Mar. 19, 2020, which claims the benefit of priority to U.S. Patent Application Ser. No. 62/729,596, filed Sep. 11, 2018, which are hereby incorporated by reference herein in their entireties.

### FIELD OF THE DISCLOSURE

This document pertains generally, but not by way of limitation, to semiconductor devices and, more particularly, to techniques for constructing enhancement mode gallium nitride devices.

### BACKGROUND

Gallium nitride-based semiconductors offer several advantages over other semiconductors as the material of choice for fabricating the next generation of transistors, or semiconductor devices, for use in both high-voltage and high-frequency applications. Gallium nitride (GaN) based semiconductors, for example, have a wide-bandgap that enable devices fabricated from these materials to have a high breakdown electric field and robustness to a wide range of temperatures. The two-dimensional electron gas (2DEG) channels formed by GaN-based heterostructures generally have high electron mobility, making devices fabricated using these structures useful in power-switching and amplification systems. GaN-based semiconductors, however, are typically used to fabricate depletion mode, or normally on, devices which can have limited use in many of these systems due to the added circuit complexity required to support such devices.

### BRIEF DESCRIPTION OF THE DRAWINGS

FIG. 1 illustrates a diagram of an enhancement mode compound semiconductor device incorporating a buried p-type region, according to various embodiments.

FIG. 2 illustrates a diagram of an enhancement mode compound semiconductor device incorporating an overlying p-type region and a buried p-type region, according to various embodiments.

FIG. 3 illustrates a diagram of an enhancement mode compound semiconductor device incorporating a recessed channel layer and a buried p-type region, according to various embodiments.

FIGS. 4A, 4B, 4C, 4D, and 4E collectively illustrate diagrams of steps for forming a gate region of an enhancement mode compound semiconductor device, according to various embodiments.

FIGS. 5A and 5B illustrate diagrams of an enhancement mode semiconductor device having a controllable buried p-type region, according to various embodiments.

FIGS. 6A and 6B illustrate diagrams of an enhancement mode semiconductor device having buried p-type region patterned with a staircase region, according to various embodiments.

FIGS. 7A and 7B illustrate diagrams of an enhancement mode semiconductor device having a buried p-type region patterned with a striped region, according to various embodiments.

FIG. 8 illustrates a diagram of a combined depletion mode compound semiconductor device and enhancement mode compound semiconductor device, according to various embodiments.

FIG. 9 illustrates a diagram of an enhancement mode semiconductor device having a buried resistor, according to various embodiments.

FIG. 10 illustrates an example of a process used to fabricate an enhancement mode compound semiconductor device, according to various embodiments.

FIGS. 11A and 11B illustrate diagrams of steps for patterning a p-type region of an enhancement mode compound semiconductor device by ion implantation, according various embodiments.

FIGS. 12A, 12B, and 12C illustrate diagrams of structures for patterning a p-type region of an enhancement mode compound semiconductor device by annealing, according to various embodiments.

FIGS. 13A, 13B, and 13C illustrate diagrams for patterning a p-type region of an enhancement mode compound semiconductor device by annealing, according various embodiments.

FIGS. 14A and 14B illustrate diagrams of structures for patterning a p-type region of an enhancement mode compound semiconductor device by annealing, according to various embodiments.

In the drawings, which are not necessarily drawn to scale, like numerals can describe similar components in different views. Like numerals having different letter suffixes can represent different instances of similar components. The drawings illustrate generally, by way of example, but not by way of limitation, various embodiments discussed in the present document.

### DETAILED DESCRIPTION

The present disclosure describes, among other things, GaN-based enhancement mode semiconductor devices (hereinafter, “enhancement mode compound semiconductor device” or “enhancement mode device”), such as transistors and switches, fabricated using a region p-type GaN material buried under the 2DEG region of a GaN-based high electron mobility transistor. These GaN-based enhancement mode semiconductor devices are useful in high frequency and high-power switching applications that require switching elements to be normally off. Such enhancement mode semiconductor devices can be integrated into the circuit designs of switching power applications with reduced circuit complexity when compared to designs using known depletion mode GaN devices, thus reducing the costs of these designs.

Illustrative examples include a GaN-based enhancement mode semiconductor device (hereinafter, “enhancement mode GaN device”), such as a high electron mobility transistor (HEMT), that can be used at high power densities and high frequencies, and methods for making such a device. The enhancement mode device can include a layer of p-type GaN-based compound semiconductor material (e.g., doped p-type material) disposed on a region of aluminum nitride (AlN) material under a 2DEG region formed by a GaN-based heterostructure. The layer of p-type material, or the region of AlN material, can be configured to determine an enhancement mode turn-on threshold voltage of the enhancement mode device, such as by depleting the 2DEG region when the enhancement mode GaN device is unbiased, such as when no voltage is applied to the gate terminal of the device. In an example, such configuration includes patterning the layer of p-type material, such as by selectively activating portions of the p-type material when the p-type material is deactivated, and selectively deactivating points of the p-type material when the p-type material is activated. In another example, such configuration includes forming the region of AlN material within a target distance below the 2DEG, such as to cause the AlN material to at least partially deplete the 2DEG.

Illustrative examples include an enhancement mode GaN device formed by recessing an area of a barrier layer of a GaN-based heterostructure, such as to deplete a 2DEG formed by the GaN-based heterostructure in a region under the recessed area. The enhancement mode GaN device further includes a gate region that is at least partially formed within the recessed area.

Illustrative examples include an enhancement mode GaN device formed according to the recessing techniques and buried region structures described herein.

As used herein a GaN-based compound semiconductor material can include a chemical compound of elements including GaN and one or more elements from different groups in the periodic table. Such chemical compounds can include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table can also be referred to as Group III and group 15 as Group V. In an example, a semiconductor device can be fabricated from GaN and aluminum indium gallium nitride (AlInGaN).

Heterostructures described herein can be formed as AlN/GaN/AlN hetero-structures, InAlN/GaN hetero-structures, AlGaN/GaN hetero-structures, or hetero-structures formed from other combinations of group 13 and group 15 elements. These hetero-structures can form a 2DEG at the interface of the compound semiconductors that form the heterostructure, such as the interface of GaN and AlGaN. The 2DEG can form a conductive channel of electrons that can be controllably depleted, such as by an electric field formed by a buried layer of p-type material disposed below the channel. The conductive channel of electrons can also be controllably enhanced, such as by an electric field formed by a gate terminal disposed above the channel to control a current through the semiconductor device. Semiconductor devices formed using such conductive channels can include high electron mobility transistors.

The layers, masks, and device structures depicted herein are formed using any suitable technique for forming (e.g., depositing, growing, patterning, or etching) such layers, masks, and device structures.

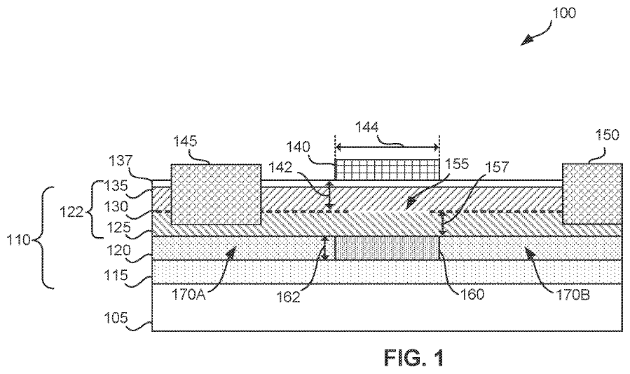

FIG. 1 illustrates a diagram of an enhancement mode compound semiconductor device 100 incorporating a buried p-type region, according to various embodiments. The enhancement mode device 100 can include an enhancement mode field-effect transistor (FET), such as an enhancement mode HEMT. Although this disclosure primarily discusses the use of GaN-based compound semiconductor materials for the fabrication of the enhancement mode device 100 and other devices discussed herein, other suitable monocrystalline compound semiconductor materials can be used, such as materials formed by group III-V compounds, such as GaAs-based compounds. The enhancement mode GaN device 100 includes a substrate 105, a device structure 110 disposed over a surface of the substrate 105, a gate electrode 140, a source electrode 145, and drain electrode 150 coupled to the device structure.

The substrate 105 includes a wafer, such as a wafer of a high-quality monocrystalline semiconductor material, such as sapphire (α-Al203), GaN, GaAs, Si, silicon carbide (SiC) in any of its polymorphs (including wurtzite), AlN, InP, or similar substrate material used in the manufacture of semiconductor devices.

The device structure 110 includes one or more layers (e.g., epitaxially formed layers) of compound semiconductor materials. Such layers can include a buffer layer 115, a doped layer 120 (e.g., a p-type layer), and a channel layer 122. The channel layer 122 can include a first layer 125 of a first compound semiconductor material and a second layer 135 (e.g., a barrier layer) of a second compound semiconductor material, such that the first compound semiconductor material has a different bandgap than the second compound semiconductor material. In an example, the first compound semiconductor material is GaN and the second compound semiconductor material is AlGaN. The channel layer 122 can also include a 2DEG region 130, formed at the interface of, or at a heterojunction formed by, the first layer 125 and the second layer 135. The 2DEG region 130 forms a conductive channel of free electrons when the enhancement mode device 100 is biased, such as to electrically couple the source electrode 145 (e.g., a source or a source region of the enhancement mode GaN device 100) and the drain electrode 150 (e.g., a drain or a drain region of the enhancement mode GaN device 100).

The buffer layer 115 includes a compound semiconductor material, such as a layer of unintentionally doped GaN having a dopant concentration of approximately 10¹⁶/cm³ and a thickness of 400-500 nm. Such material can be formed as a thin-film by epitaxial growth, or by using other thin-film formation techniques, such as chemical vapor deposition. The buffer layer can also include one or more additional layers, such as a nucleation layer for growing additional compound semiconductor layers.

The doped layer 120 can include a layer of a monocrystalline compound semiconductor material, such as a layer of p-type GaN (p-GaN). Such layer can have a thickness of approximately 100 nm and can be configured to enable enhancement mode operation of the enhancement mode device 100. Such configuring can include selecting a dopant material and a dopant concentration of the dopant material to determine an enhancement mode turn-on threshold voltage (hereinafter, “enhancement mode threshold voltage”) to permit current flow between the source electrode 145 and the drain electrode 150 of the enhancement mode device 100. Such dopant material can be any p-type dopant that can be combined with the monocrystalline compound semiconductor material, such as a compound including magnesium (Mg). Such doping concentration can be selected using known techniques based on, among other things, a desired enhancement mode threshold voltage, a work function of the material used to form the gate electrode 140, a distance 142 from the gate electrode to the 2DEG region 130, and a thickness of a gate oxide layer 137. In some embodiments, the dopant concentration can also be selected as a function of a distance 157 from the doped layer 120 to the 2DEG region 130. In some embodiments, the doped layer 120 can be approximately 100 nm thick, the distance 142 from the gate electrode to the 2DEG region 130 can be approximately 30 nm, the distance 157 from the doped layer 120 to the 2DEG 130 can be approximately 30 nm, and the dopant concentration can be less than 10¹⁸/cm³.

In some embodiments, the doped layer 120 can include a region 160 (e.g., a buried p-type region) of activated p-type material (hereinafter, activated region 160), disposed under the gate electrode 140. The doped layer 120 can also include regions 170A and 170B of deactivated p-type material (hereinafter, deactivated regions 170A and 170B). The activated region 160 can be configured to deplete a region 155 of the 2DEG region 130, such as to determine an enhancement mode threshold voltage of the enhancement mode device 100. In some embodiments, an electrical charge on the activated region 160 can generate an electric field that displaces or depletes free electrons in the 2DEG region 130 in the region 155. Configuring the activated region 160 can include selecting the concentration of the activated p-type dopant in the activated region, the vertical distance 157 of the activated region from the 2DEG region 130, or the geometry (e.g., the length, width, or thickness 162 of the activated region), to deplete the 2DEG in the region 155 when the enhancement mode device 100 is unbiased.

In some embodiments, the enhancement mode device 100 can include a passivation layer 137, such as a gate oxide layer, disposed between the structure 122 and the gate electrode 140.

The gate electrode 140 can be any electrically conductive material selected to bias or control the enhancement mode device 100, such as a metal having a work function which operates in conjunction with the activated region 160 to enable enhancement mode operation of the enhancement mode device 100. In some embodiments, the gate electrode 140 can be configured, such as by selecting a width 144 of the gate electrode and a metal gate material with a desired work function, to restore the 2DEG in the region 155 when a bias voltage applied to the gate electrode exceeds the enhancement mode threshold voltage of the enhancement mode device 100. The fabrication of the enhancement mode device 100 using the activated region 160 can reduce the distance 142 from the gate electrode 140 to the 2DEG region 130 as compared to other enhancement mode devices. This reduced distance can increase the effectiveness of the electric field generated by the gate electrode at restoring the 2DEG, which in turn can enable the enhancement mode device 100 to be fabricated with a gate electrode having a shorter width 144.

The source electrode 145 and the drain electrode 150 can be any suitable electrically conductive material capable of forming an ohmic contact or other electrically conductive junction with the 2DEG region 130.

In certain examples, a region of AlN can replace the activated region 160. In these examples, the doped layer 120 can be replaced with any suitable doped or undoped material, such as the material of the buffer layer 115. The region of AlN is formed within an indicated distance, such as the distance 157, of the interface of the first layer 125 and the second layer 135, such as to cause the region of AlN to at least partially deplete any 2DEG formed at the interface above the region of AlN. In an example, the indicated distance is a distance determined to enable the region of AlN to deplete the 2DEG formed at the interface of the first layer and the second layer by an indicated amount. In another example, the indicated distance is determined based on a target turn-on voltage for the enhancement mode GaN device 100. In yet another example, the indicated distance corresponds to the thickness of the first layer, such as where such thickness is 5-30 nm.

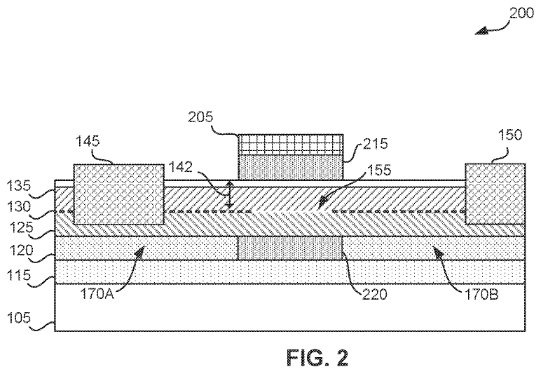

FIG. 2 illustrates a diagram of an enhancement mode compound semiconductor device 200 incorporating an overlying p-type region 215 and a buried p-type region 220, according to various embodiments. The enhancement mode device 200 can be an example of the enhancement mode device 100, modified to include the overlying p-type region 215. The enhancement mode device 200 can include, in addition to the layers and regions of the enhancement mode device 100, a gate electrode 205, the overlying p-type region 215, and the buried p-type region 220. The overlying p-type region 215 can include an activated p-type material, such as activated p-GaN. The gate electrode 205 and the buried p-type region 220 can be substantially similar to the gate electrode 140 and the activated region 160, as shown in FIG. 1. The buried p-type region 220 can operate in conjunction with the overlying p-type region 215 to deplete a region 155 of the 2DEG region 130, such as to enable enhancement mode operation of the enhancement mode device 200 or to determine an enhancement mode threshold voltage of the enhancement mode device, as described herein.

In some embodiments, the electrical charge of the buried p-type region 220 and an electrical charge of the overlying p-type region 215 can generate a first electric field and a second electric field that displaces, or depletes, free electrons in the 2DEG region 130 at the region 155. The combined operation of the first and second electric fields can result in increased depletion in the region 155 of the enhancement mode device 200, as compared to the depletion in the corresponding region of the enhancement mode device 100. In some embodiments, the combined operation of the first and second electric fields can enable the enhancement mode device 200 to have similar electrical characteristics, such as an enhancement mode threshold voltage, as the enhancement mode device 100, while permitting the buried p-type region 220 to have a lower activated dopant concentration than the dopant concentration of the activated region 160.

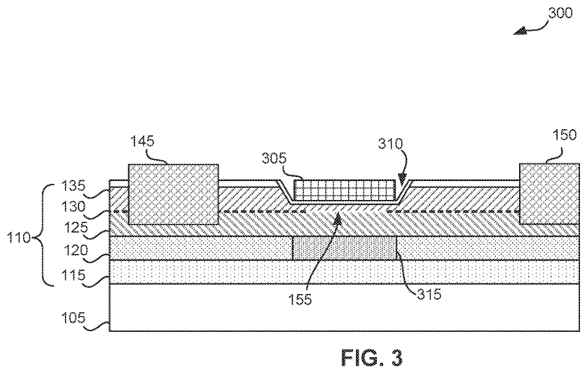

FIG. 3 illustrates a diagram of an enhancement mode compound semiconductor device 300 incorporating a recess 310 in the channel layer 110 and a buried p-type region 315, according to various embodiments. The enhancement mode device 300 can be an example of the enhancement mode device 100, modified to include the recess 310. The enhancement mode device 300 can include, in addition to the indicated layers and regions of the enhancement mode device 100, a gate electrode 305, a recess 310, and a buried p-type region 315. The recess 310 can be formed, such as by an etching process, above the 2DEG region 130, so as to reduce the distance from the gate electrode 305 to the 2DEG region 130 while not interrupting or interfering with the 2DEG region. In some embodiments, the recess 310 can be formed in the second layer 135. The gate electrode 305 and the buried p-type region 315 can be substantially similar to the gate electrode 140 and the activated region 160, as shown in FIG. 1. The gate electrode 305 and the buried p-type region 315, however, can be modified, due to the reduced distance between the gate electrode and the 2DEG region 130, while permitting the enhancement mode device 300 to maintain substantially similar device characteristics as the enhancement mode device 100. Such modifications can include reducing the length or thickness of the gate electrode 305, as compared to the length or thickness of the gate electrode 140. Such modifications can also include permitting the buried p-type region 315 to have a lower activated dopant concentration than the dopant concentration of the activated region 160.

In some embodiments, the gate electrode 305 or the buried p-type region 315 can have a geometry or a chemical composition that is substantially similar to the geometry or chemical composition of the gate electrode 140 or the activated region 160. In these embodiments, the reduced distance between the gate electrode 305 and the 2DEG 130 can cause the enhancement mode device 300 to have a stronger on-state, or to permit a greater current flow between the source electrode 145 and the drain electrode 150, while the enhancement mode device is biased.

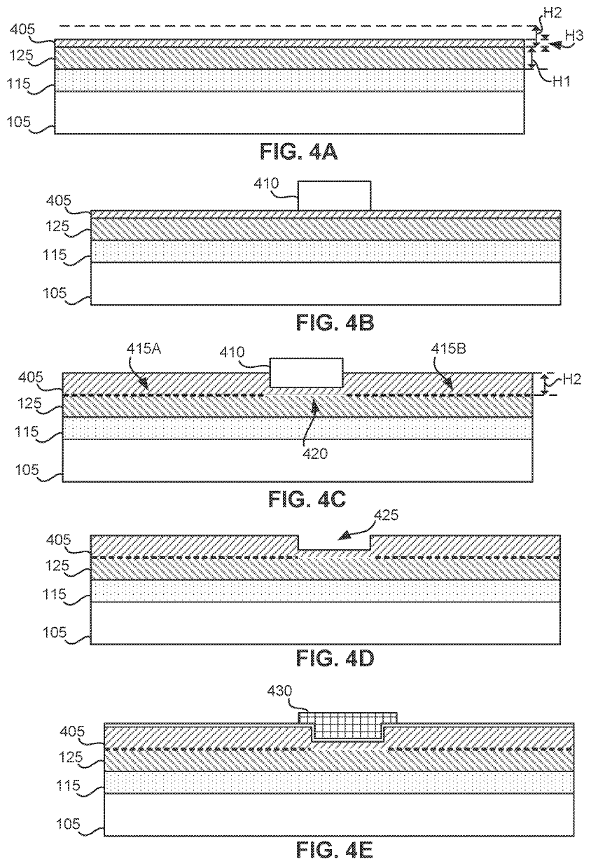

FIGS. 4A, 4B, 4C, 4D, and 4E collectively illustrate diagrams of a process for forming a recessed gate region, or for recessing a gate region, of an enhancement mode compound semiconductor device, such as the enhancement mode device 300 (FIG. 3). In an example, the process illustrated in FIGS. 4A, 4B, 4C, 4D, and 4E are used to recess an AlGaN barrier using epitaxy. The process can be used to fabricate an enhancement mode device that has better stability and reliability than enhancement mode devices that are fabricated using other techniques, such as etching.

The process includes forming, or obtaining, the initial device structure shown in FIG. 4A. In an example, the initial device structure includes the substrate layer 105, the buffer layer 115, and a partially formed channel layer including a GaN-based heterojunction formed by the GaN-based compound semiconductor layers 125 and 405. The compound semiconductor layer 125 includes a first GaN-based compound semiconductor material, as described in the discussion of FIGS. 1-3, while a compound semiconductor layer 405 includes a second GaN-based compound semiconductor material that is selected to have a different bandgap than the first compound semiconductor material. In an example, the first compound semiconductor material is GaN and the second compound semiconductor material is AlGaN.

In the completed enhancement mode device, the compound semiconductor layer 125 is formed to at least a first target height H1 while the compound semiconductor layer 405 is formed to a second target height H2, such as to enable a 2DEG to form at the interface between the compound semiconductor layer 125 and the compound semiconductor layer 405. The target height H1 and the target height H2 can be determined, or selected, based on one or more parameters, such as a desired electrical or size characteristic of the enhancement mode device or properties of the first or second compound semiconductor material. In an example, the height H1 is determined based on a target turn-on voltage of the enhancement mode semiconductor device. The height H1 can determine, or is indicative of, the unbiased or unpowered electrical characteristics of the enhancement mode device (e.g., the source-drain conductivity of the device when no voltage is applied to the gate of the device or the required gate voltage for forming the conductive channel between the source and drain). At the process step shown in FIG. 4A, the compound semiconductor layer 405 is grown to a height H3 that is less than H2. The height H3 can be selected to determine an electrical or geometric characteristic of the enhancement mode device. In an example, the height H3 corresponds to the formation of an amount of the second compound semiconductor material that is insufficient to form a conductive channel of a 2DEG at the interface of the compound semiconductor layer 125 and the compound semiconductor layer 405 without biasing by an electric field, such as an electric field formed between a gate contact of the enhancement mode device and the first compound semiconductor material in the layer 125. In an example, the height H3 is 5-30 nm.

In an example, the structure shown in FIG. 4A can include a doped layer, such as the doped layer 120 (FIGS. 1-3), disposed between the buffer layer 115 and the compound semiconductor layer 405. The doped layer can be patterned to include a region (e.g., the region 160, 220, or 315) of material that is configured to deplete, or inhibit the formation of, a 2DEG formed at the interface of the compound semiconductor layer 125 and 405. In an example the patterned region can include an activated p-type material or an AlN material, as described herein.

The process step depicted by the structure shown in FIG. 4B includes forming a hard mask 410 on the compound semiconductor layer 405 (e.g., a GaN barrier layer). The hard mask 410 is formed at any location where the compound semiconductor layer 405 for the completed enhancement mode device is thinned, such as to inhibit formation of a conductive channel of 2DEG, such as when the completed enhancement mode device is unpowered, such as when a gate voltage is not applied to the completed enhancement mode device. In an example, the hard mask 410 is formed at a designated or specified location of a gate contact of the enhancement device and has a geometry that substantially corresponds to the geometry of the gate terminal. The hard mask is formed using any suitable material, such as SiN or SiO.

The process step depicted by the structure shown FIG. 4C includes further forming, or developing, the compound semiconductor layer 405, such as to increase the thickness of the layer 405 to H2. As shown in FIG. 4C, the increased thickness of the compound semiconductor layer 405 can cause a 2DEG to be formed in regions 415A and 415B. The 2DEG, however, is not formed in region 420 where hard mask 410 inhibits the thickness of the compound semiconductor layer 405 from becoming larger than H3.

The process step depicted by the structure shown FIG. 4D includes removing the hard mask 410 to expose the recess 425.

The process step depicted by the structure shown FIG. 4D includes forming a gate 430 of the enhancement device, such as by deposition of a gate dielectric and a metal contact material in or around the recess 425. The process can be continued with any additional steps that are suitable for completing the fabrication of the enhancement mode device.

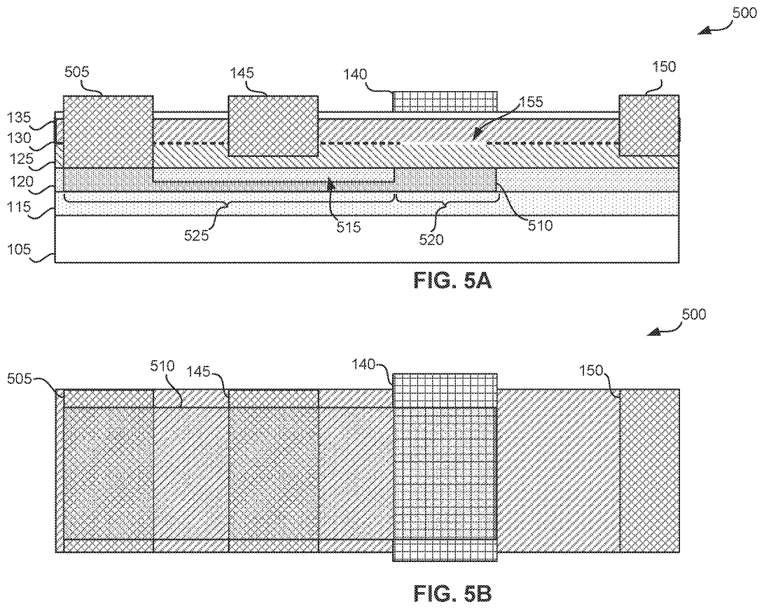

FIG. 5A and FIG. 5B illustrate diagrams of an enhancement mode semiconductor device 500 having a controllable buried p-type region 510, according to various embodiments. FIG. 5A shows a cross section of the enhancement mode device 500 while FIG. 5B shows a top-down view of the enhancement mode device. The enhancement mode device 500 can be an example of the enhancement mode device 100, modified to include a control electrode 505 and the controllable buried p-type region 510. The control electrode 505 can include any suitable electrically conductive material, such as a metal selected to form an ohmic contact with the controllable buried p-type region 510. The controllable buried p-type region 510 can be an activated p-type region, such as the region 160 (FIG. 1). The controllable buried p-type region 510 can include a first region 520 disposed under the gate electrode 140, and a second region 525 that extends under the source contact 145 to contact the control electrode 505. The first region 520 can be configured to determine the enhancement mode threshold voltage of the enhancement mode device 500, as described herein. The second region 525 can be configured to couple a control signal, such as an electrical charge, from the control electrode 505 to the first region 520. The second region 525 can include a region of deactivated p-type material 515. In some embodiments, the region of deactivated p-type material 515 can be formed by deactivating a portion of the second region 525 between the gate electrode 140 and the control electrode 505, such as by using an ion implantation process. The region of deactivated p-type material 515 can limit the effect that the controllable buried p-type region 510 has on the 2DEG region 130 in the region between the gate electrode and the source electrode, such as to limit the depletion of the 2DEG region 130 to the region 155 under the gate electrode 140.

In operation of the enhancement mode device 500, a voltage can be applied to the control electrode 505, such as to modify the electrical charge in the first region 520 of the controllable buried p-type region 510, such as to modify the enhancement mode threshold voltage of the enhancement mode device.

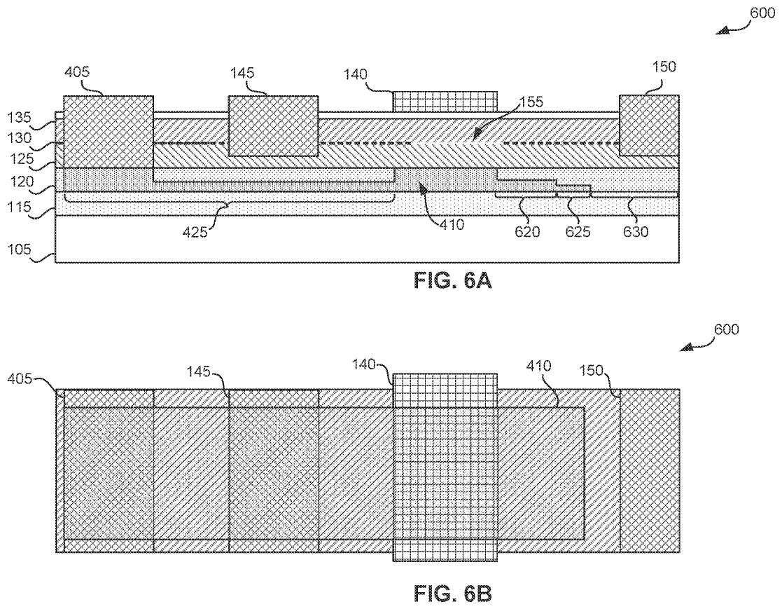

FIG. 6A and FIG. 6B illustrate diagrams of an enhancement mode semiconductor device 600 having buried p-type region patterned with a staircase region 620, 625, or 630, according to various embodiments. FIG. 6A shows a cross section of the enhancement mode device 600 while FIG. 6B shows a top-down view of the enhancement mode device. The enhancement mode device 600 can be an example of the enhancement mode device 500, modified to include the staircase region 620, 625, or 630. The staircase region 620, 625, or 630 can be formed from the doped layer 120, such as a layer of activated p-type material, by selectively deactivating the p-type dopant in region 620, 625, or 630, such as by using an ion implantation process to implant hydrogen at a first, second, and third depth, respectively, such that the implantation depth increases from the gate electrode 140 towards the drain electrode 150. Alternately, the staircase region 620, 625, or 630 can be formed from the layer 120, such as layer of activated p-type material, by selectively deactivating the p-type dopant in region 620, 625, or 630, such as by using an ion implantation process to implant hydrogen in a first, second, and third concentration, respectively, such that the implantation concentration decreases from the gate electrode 140 towards the drain electrode 150. The staircase region 620, 625, or 630 can operate as a back-side field plate, such as to reduce an electric field between the gate electrode 140 and the drain electrode 150, such as to enable the enhancement mode device 600 to be driven by high voltages, as compared to other enhancement mode devices.

In some embodiments, the enhancement mode device 600 can be fabricated without the control electrode 405 or the region 425. In certain embodiments, the staircase region 620, 625, or 630 can be formed under the gate electrode 140 to towards the source electrode 145.

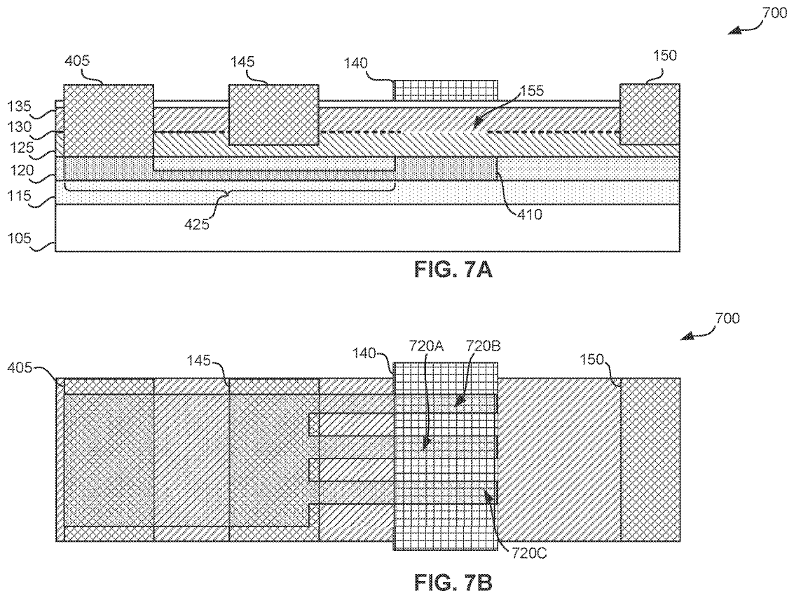

FIG. 7A and FIG. 7B illustrate diagrams of an enhancement mode semiconductor device 700 having a buried p-type region patterned with a striped region 720A, 720B, or 720C, according to various embodiments. FIG. 7A shows a cross section of the enhancement mode device 700 while FIG. 7B shows a top-down view of the enhancement mode device 700. The enhancement mode device 700 can be an example of the enhancement mode device 500, modified to include the striped region 720A, 720B, or 720C in the burred p-type region 510. In some embodiments, the enhancement mode device 700 can be fabricated without the control contact 405 or the region 425.

The striped region 720A, 720B, or 720C can be formed under the gate electrode 140 using the doped layer 120, such as a layer of activated p-type material, by selectively deactivating the p-type dopant outside of the striped region, such as by using an ion implantation process, as described herein. Alternatively, the striped region 720A, 720B, or 720C can be formed under the gate electrode 140 from a doped layer 120, such as of deactivated p-type material, by selectively activating the p-type dopants in at least the region 720A, 720B, or 720C, such as by using an annealing process, as described herein. One or more of the striped regions 720A, 720B, or 720C can have different doping levels than one or more of the other striped regions 720A, 720B, or 720C, such as to determine two or more enhancement mode threshold voltages for the enhancement mode device 700. Such different doping levels can include different activated dopant materials, different concentrations of activated dopant material, or different depths to which the dopants are activated or deactivated in the buried p-type region 510.

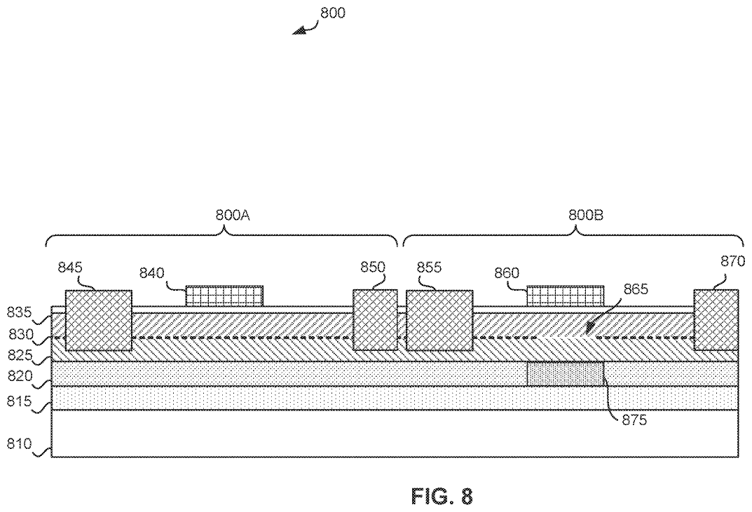

FIG. 8 illustrates a diagram of a semiconductor device 800 having a combined depletion mode compound semiconductor device (hereinafter, “depletion mode device”) 800A and an enhancement mode compound semiconductor device 800B, according to various embodiments. The depletion mode device 800A can be an example of a depletion mode FET, such as a depletion mode HEMT. The enhancement mode device 800B can be an example of an enhancement mode device 100 (FIG. 1). The depletion mode device 800A and the enhancement mode device 800B can include a substrate 810, and a device structure including a buffer layer 815, a doped layer 820 of a deactivated p-type compound semiconductor material, a first layer 825 of a first compound semiconductor material, a second layer 835 of a second compound semiconductor material, and a 2DEG region 830 formed at the interface of the first layer and the second layer. The depletion mode device 800A can additionally include a gate electrode 840, a source electrode 845, and a drain electrode 850. The enhancement mode device 800B can additionally include a gate electrode 860, a source electrode 855, and a drain electrode 870. The enhancement mode device 800B can further include a buried p-type region 875 that is configured deplete a region 865 of the 2DEG. The buried p-type region 875 can be configured to determine an enhancement mode threshold voltage of the enhancement mode device 800B, as described herein.

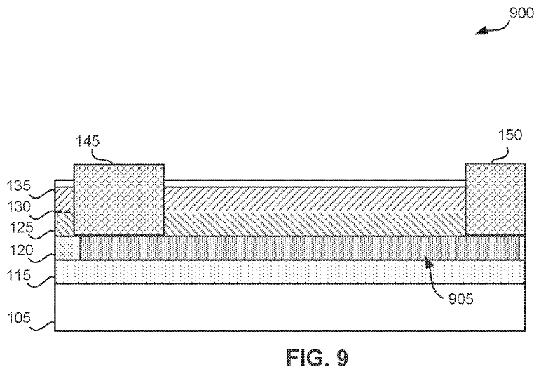

FIG. 9 illustrates a diagram of an enhancement mode semiconductor device 900 having a buried resistor 905, according to various embodiments. The enhancement mode device 900 can be substantially similar to the enhancement mode device 100, modified to cause the source electrode and the drain electrode to contact the buried resistor 905. The buried resistor 905 can include an activated region of the doped layer 120. The activated region can be configured to have a specified concentration of activated dopants, such as to determine a sheet resistance of the activated region. Such sheet resistance can range from 300 ohms per square (Ohms/sq.) to 1000 ohms/sq. The buried resistor 905 can have a high resistance while having a small or reduced overall area, as compared to device resistors formed by other techniques, due this attainable sheet resistance. Consequently, devices fabricated using the buried resistor 905 can be have a smaller circuit area than devices fabricated using resistors formed by other techniques.

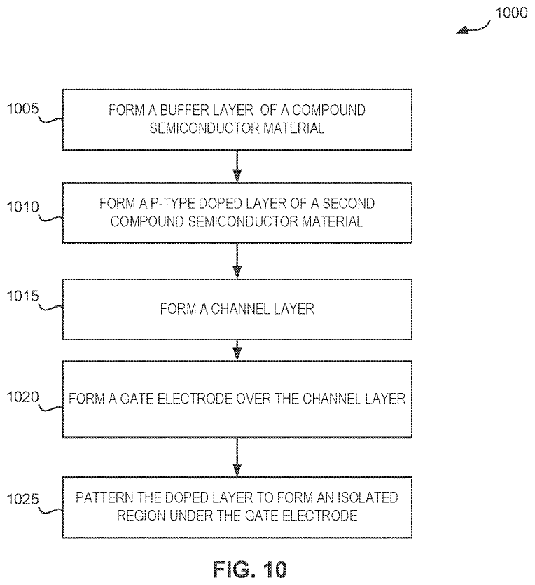

FIG. 10 illustrates an example of a process 1000 that can be used to fabricate an enhancement mode compound semiconductor device, according to various embodiments. The process 1000 can be used to fabricate any other enhancement mode device described herein. The process 1000 can begin by receiving a substrate having a substantially crystalline structure. Such substrate can be received from a prior fabrication process or it can be produced according to one or more substrate growth and processing techniques. Such substrate can be a wafer, such as a wafer of sapphire (α-Al203), GaN, GaAs, Si, SiC in any of its polymorphs (including wurtzite), AlN, InP, or similar substrate material used in the manufacture of semiconductor devices.

At 1005, a buffer layer of a first compound semiconductor material can be formed over a surface of the substrate. The buffer layer can include a heteroepitaxial GaN thin-film, such as thin-film formed by epitaxial growth, or by using another thin-film formation technique, such as chemical vapor deposition (CVD), such as to have a depth of approximately 400-500 nm thick.

At 1010, a doped layer (e.g., a p-typed layer) of a second compound semiconductor material can be formed over the buffer layer. Such second compound semiconductor material can be epitaxially grown over the buffer layer to a thickness of 100 nm using any suitable process. Such second compound semiconductor material can be doped with a p-type dopant, such as Mg. In some embodiments, the p-type dopant can be deactivated, such as by reacting the dopant with a deactivating material, such as hydrogen.

At 1015, a channel layer can be formed over the doped layer. Forming the channel layer can include forming a first layer of a third compound semiconductor material over the doped layer, followed by forming a second layer of a fourth compound semiconductor material over the first layer. The first layer of third compound semiconductor material can be formed in substantially the same manner as the buffer layer, such as by epitaxial growth, or using another thin-film formation technique. In some embodiments, the first layer of a third compound semiconductor material can be a 100 nm thick GaN layer. The second layer of the fourth compound semiconductor material can be a 30 nm thick AlGaN layer grown over a surface of the first layer, such as by using any suitable thin-film formation technique. The third compound semiconductor material and the fourth compound semiconductor material can be selected to have different bandgaps, such as to form a heterojunction at the interface between the first layer and the third layer. Such a selection can enable a 2DEG to form at the heterojunction, such as to form a 2DEG region at the heterojunction.

At 1020, a gate electrode can be formed over the channel layer. Such gate electrode can include any suitable gate material, selected to enable enhancement mode operation of the enhancement mode device, as described herein.

At 1025, the doped layer can be patterned, such as to form an isolated region (e.g., a buried activated p-type region) under the gate electrode.

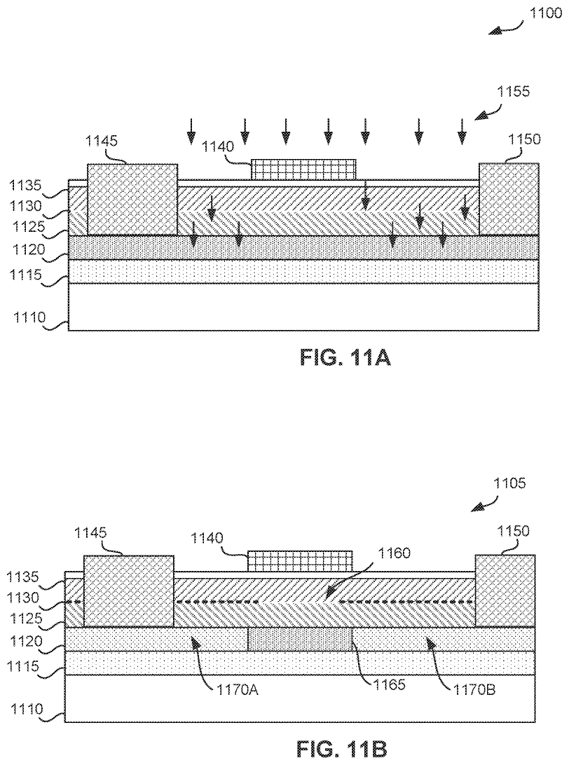

With reference to FIG. 11A and FIG. 11B, patterning the doped layer can include using an ion implantation technique to selectively deactivate regions of the doped layer. FIG. 11A and FIG. 11B illustrate diagrams of steps in the ion implantation process.

FIG. 11A depicts an example enhancement mode device 1100 having substrate layer 1110, a buffer layer 1115, a doped layer 1120, a compound semiconductor layer 1125 (e.g., a first layer of a third compound semiconductor), a 2DEG region 1130, a compound semiconductor layer 1135 (e.g., a second layer of a fourth compound semiconductor), a gate electrode 1140, a source electrode 1145, and a drain electrode 1150. The doped layer 1120 can include a layer of an activated p-type material. As depicted in FIG. 11A, the doped layer 1120 can be patterned by using the gate electrode 1140 as a mask to selectively implant a deactivating material 1155 into regions of the doped layer exposed by the gate electrode, such as to self-align the resultant activated p-type region under the gate electrode. While FIG. 11A depicts the gate electrode 1140 as being used for the ion implantation mask, any other suitable mask can be used.

FIG. 11B depicts an example enhancement mode device 1105 after the ion implantation process. As shown in FIG. 11B, the ion implantation process deactivated the p-type material in the regions 1170A and 1170B that were exposed by the gate electrode, while leaving activated the p-type material in the masked region 1165 of the d layer 1120. As a result of the ion implantation process, the 2DEG region 1130 is restored, except at the region 1160, which is depleted by the masked region 1165.

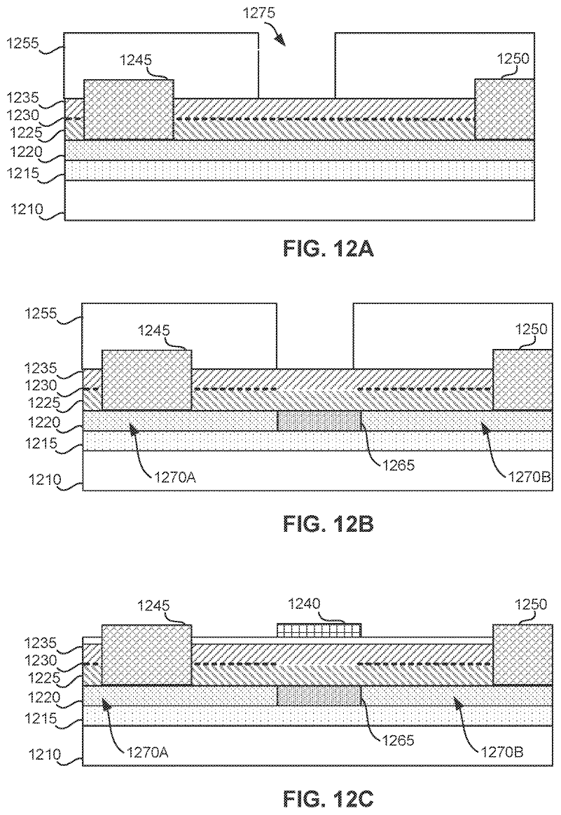

Returning to the process 1000, with reference to FIGS. 12A, 12B, and 12C, patterning the doped layer can include using an annealing process to selectively activate regions of the doped layer, such as when the doped layer includes a layer of deactivated p-type material. FIGS. 12A, 12B, and 12C illustrate diagrams of device structures for patterning a p-type region of an enhancement mode compound semiconductor device using an annealing process before forming the gate electrode over the channel layer.

The structure in FIG. 12A can include a passivation layer 1255, and a partially fabricated enhancement mode device having substrate layer 1210, a buffer layer 1215, a doped layer 1220, a compound semiconductor layer 1225 (e.g., a first layer of a third compound semiconductor), a 2DEG region 1230, a compound semiconductor layer 1235 (e.g., a second layer of a fourth compound semiconductor), a source electrode 1245, and a drain electrode 1250. The doped layer 1220 can include a layer of deactivated p-type material, such as deactivated p-GaN. The passivation layer 1255 can include a layer of any suitable passivation material, such as silicon nitride. As depicted in FIG. 12A, the doped layer 1220 can be patterned by forming a cavity 1275 in the passivation layer 1255, such as to expose a region of the compound semiconductor layer 1235 between the source electrode 1245 and the drain electrode 1250. The structure can then annealed in an N₂ or NH₃ environment, such as in a chamber filed with an ambient N₂/NH₃ gas and heated to an annealing temperature between 1100 and 1200 degrees Celsius (° C.). As shown in FIG. 12B, such annealing can activate a region 1265 of the doped layer 1220 under the cavity 1275, while leaving the regions 1270A and 1270B deactivated. The passivation layer 1255 can then be removed and the gate electrode 1240 can be formed using know techniques, as shown in FIG. 12C.

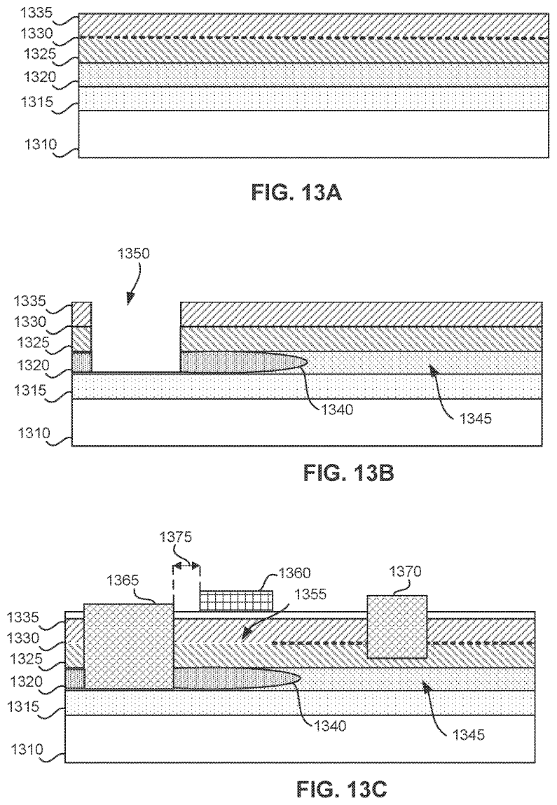

Returning to the process 1000, with reference to FIGS. 13A, 13B and 13C, patterning the doped layer can include using an annealing process to selectively activate regions of the doped layer, such as when the doped layer includes a layer of deactivated p-type material. FIGS. 13A, 13B, and 13C illustrate diagrams for patterning a p-type region of an enhancement mode compound semiconductor device by annealing, according various embodiments. Such patterning can be used to form an enhancement mode compound semiconductor device having a gate electrode within a threshold distance from a source electrode.

FIG. 13A depicts a partially fabricated enhancement mode device, including a substrate layer 1310, a buffer layer 1315, a doped layer 1320, a compound semiconductor layer 1325 (e.g., a first layer of a third compound semiconductor), a 2DEG region 1330, and a compound semiconductor layer 1335 (e.g., a second layer of a fourth compound semiconductor). The doped layer 1320 can include a layer of deactivated p-type material. Patterning the doped layer 1320 can include forming a cavity or recess 1350 in the partially complete enhancement mode device as shown in FIG. 13B. The partially complete enhancement mode device can then be annealed in a N₂/NH₃ environment as previously described, such as to activate a region 1340 of the doped layer 1320, while leaving the region 1345 deactivated. Fabrication of the enhancement mode device can then be continued, such as by forming the gate electrode 1360, the source electrode 1365, and the drain electrode 1370, as shown in FIG. 13C. Such gate electrode 1360 be formed within a distance (a gate-source distance) 1375 from the source electrode, such as to enable electrons from the source electrode to be able to tunnel through the depletion region 1355 to reach drain electrode 1370 when the enhancement mode device is turned on, such as when a sufficient turn on voltage is applied to the gate electrode. This patterning can be used to form an enhancement mode compound semiconductor device having a gate-source distance 1375 that is shorter than 100 nm.

Returning again to the process 1000, the process can include forming, before forming the gate electrode, a recess in the channel layer, such as in the second layer of the fourth compound semiconductor material. The gate electrode can then be formed, at least partially, in the recess.

In some embodiments, the process 1000 can include forming a second doped layer (e.g., a second p-type doped layer) between the gate electrode and the channel layer. The process 1000 can further include patterning the first doped layer formed at 1010 and the second doped layer using the gate electrode as a mask, such as in an ion implantation process.

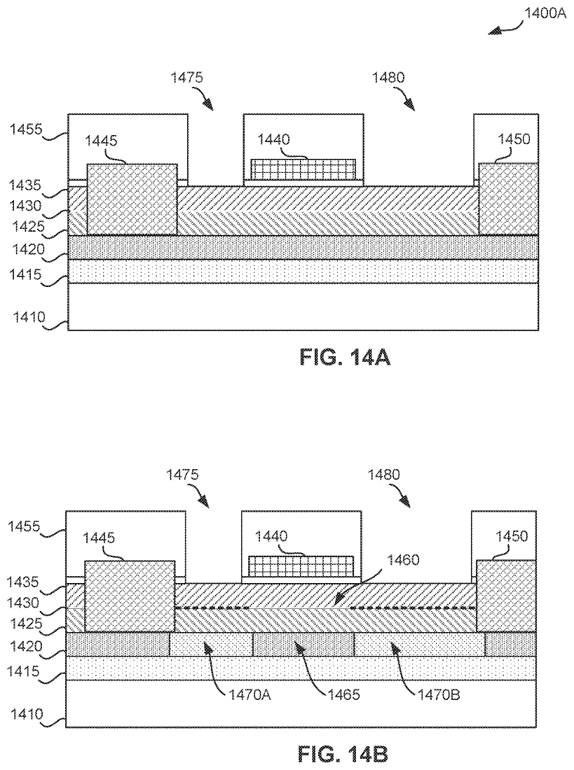

Returning to the process 1000, with reference to FIGS. 14A, and 14B, patterning the doped layer can include using an annealing process to selectively deactivate regions of the doped layer, such as when the doped layer includes a layer of activated p-type material. FIGS. 14A, and 14B illustrate diagrams of device structures for patterning a p-type region of an enhancement mode compound semiconductor device using an annealing process after forming the gate electrode over the channel layer.

The structure 1400A in FIG. 14A can include a passivation layer 1455, and an enhancement mode device having substrate layer 1410, a buffer layer 1415, a doped layer 1420, a compound semiconductor layer 1425 (e.g., a first layer of a third compound semiconductor), a 2DEG region 1430, a compound semiconductor layer 1435 (e.g., a second layer of a fourth compound semiconductor), a source electrode 1445, and a drain electrode 1450. The doped layer 1420 can include a layer of activated p-type material, such as activated p-GaN. The passivation layer 1455 can include a layer of any suitable passivation material, such as silicon nitride. As depicted in FIG. 14A, the doped layer 1420 can be patterned by forming a first cavity 1475 and a second cavity 1480 in the passivation layer 1455, such as to expose both a first region of the compound semiconductor layer 1435 between the source electrode 1445 and the gate electrode 1440, and a second region of the compound semiconductor layer 1435 between the gate electrode 1440 and the drain electrode 1450. The structure can then be annealed in an environment including an activating material, such as an H₂ annealing environment. As shown in FIG. 14B, such annealing can deactivate a first region 1470A and a second region 1470B of the doped layer 1420 under the cavities 1475 and 1480, respectively, while leaving the region 1465 activated. The activated region 1465 can deplete a region 1460 of the 2DEG.

Although the above discussion discloses various example embodiments, it should be apparent that those skilled in the art can make various modifications that will achieve some of the advantages of the invention without departing from the true scope of the invention.

Each of the non-limiting aspects or examples described herein can stand on its own, or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. (canceled)

2. A method of manufacturing a semiconductor device, the method comprising:
forming a layer of deactivated p-type material over a substrate;
forming a layer of a first compound semiconductor material over the layer of deactivated p-type material;
forming a channel layer having a hetero-structure by forming a layer of a second compound semiconductor material over the layer of the first compound semiconductor material;
forming a recess in the channel layer and the layer of deactivated p-type material; and
forming an activated p-type region adjacent the recess in the layer of deactivated p-type material by annealing the semiconductor device while leaving a deactivated p-type region.

3. The method of claim 2, further comprising:
forming a gate electrode;
forming a source electrode within the recess and adjacent the gate electrode; and
forming a drain electrode.

4. The method of claim 3, wherein the recess is a first recess, the method comprising:
forming a second recess within the channel layer, and wherein forming the gate electrode includes:
forming the gate electrode at least partially within the second recess.

5. The method of claim 3, wherein forming the activated p-type region in the layer of deactivated p-type material includes:
forming the activated p-type region under the gate electrode.

6. The method of claim 3, wherein forming the source electrode includes:
forming the source electrode laterally within 100 nanometers of the gate electrode.

7. The method of claim 2, wherein annealing the semiconductor device includes:
annealing in an environment comprising nitrogen.

8. The method of claim 2, wherein annealing the semiconductor device includes:
annealing in an environment comprising ammonia.

9. The method of claim 2, wherein annealing the semiconductor device includes:
annealing at a temperature between 1100 and 1200 degrees Celsius.

10. The method of claim 2, wherein the first compound semiconductor material comprises gallium nitride (GaN) and the second compound semiconductor material comprises aluminum gallium nitride (AlGaN).

11. The method of claim 2, wherein forming the layer of deactivated p-type material includes forming a layer of deactivated p-type gallium nitride (p-GaN).

12. The method of claim 2, wherein the semiconductor device is an enhancement mode semiconductor device.

13. A semiconductor device comprising:
a substrate;
a layer of deactivated p-type material disposed over the substrate;
a layer of a first compound semiconductor material disposed over the layer of deactivated p-type material;
a channel layer having a hetero-structure comprising a layer of a second compound semiconductor material disposed over the layer of the first compound semiconductor material;
a recess formed in the channel layer and the layer of deactivated p-type material;
an activated p-type region formed in the layer of deactivated p-type material and adjacent the recess;
a deactivated p-type region formed adjacent to the activated p-type region;
a source electrode formed in the recess; and
a gate electrode formed over the activated p-type region and adjacent the source electrode.

14. The semiconductor device of claim 13, wherein the recess is a first recess, the semiconductor device further comprising:
a second recess formed within the channel layer, wherein the gate electrode is formed at least partially within the second recess.

15. The semiconductor device of claim 13, wherein the source electrode is formed laterally within 100 nanometers of the gate electrode.

16. The semiconductor device of claim 13, wherein the semiconductor device is an enhancement mode semiconductor device.

17. The semiconductor device of claim 13, wherein the first compound semiconductor material comprises gallium nitride (GaN) and the second compound semiconductor material comprises aluminum gallium nitride (AlGaN).

18. The semiconductor device of claim 13, wherein the layer of deactivated p-type material includes deactivated p-type gallium nitride (p-GaN).

19. A semiconductor device comprising:
a substrate;
a layer of deactivated p-type material disposed over the substrate;
a layer of a first compound semiconductor material disposed over the layer of deactivated p-type material;
a channel layer having a hetero-structure comprising a layer of a second compound semiconductor material disposed over the layer of the first compound semiconductor material;
a first recess formed in the channel layer and the layer of deactivated p-type material;
a second recess formed in the channel layer;
an activated p-type region formed in the layer of deactivated p-type material and adjacent the first recess;
a deactivated p-type region formed adjacent to the activated p-type region;
a source electrode formed in the first recess; and
a gate electrode formed over the activated p-type region and adjacent the source electrode, wherein the gate electrode is formed within the second recess.

20. The semiconductor device of claim 19, wherein the source electrode is formed laterally within 100 nanometers of the gate electrode.

21. The semiconductor device of claim 19, wherein the layer of deactivated p-type material includes deactivated p-type gallium nitride (p-GaN).
